(19) United States
(12) Patent Application Publication
(10) Pub. No.: US 2008/0238459 A1
(43) Pub. Date: Oct. 2, 2008

(54) Testing apparatus and method

(75) Inventor: Ji-Jen Chiu, Hsin-Chu (TW)

Correspondence Address: RABIN & Berdo, PC, 1101 14TH STREET, NW, SUITE 500, WASHINGTON, DC, 20005, US

(73) Assignee: AU OPTRONICS CORP., Hsin-Chu (TW)

(21) Appl. No.: 11/896,218

(22) Filed: Aug. 30, 2007

(30) Foreign Application Priority Data
Mar. 30, 2007 (TW) 96111399

(51) Int. Cl. G01R 31/02

(52) U.S. Cl. 324/756

(57) ABSTRACT

A testing apparatus includes a circuit board and a first probe. The circuit board has a first testing point and a second testing point. The first testing point is electrically connected to an integrated circuit, and the second testing point is electrically connected to the first testing point. The first probe is used for electrically contacting with the first testing point and transmitting a signal to the integrated circuit through the first testing point. The second testing point is used for detecting if the first probe electrically contacts with the first measuring point. A testing method is also disclosed herein.

### RELATED APPLICATIONS

This application claims priority to Taiwan Patent Application Serial Number 96111399, filed Mar. 30, 2007, which is herein incorporated by reference.

### BACKGROUND

1. Field of Invention

The present invention relates to a testing apparatus and method. More particularly, the present invention relates to a testing apparatus and method adopted before burning a driving integrated circuit (IC).

2. Description of Related Art

In recent years, technology has continued to develop significantly and different types of electronic products available change day by day. Among the various electronic products, liquid crystal displays have many advantages such as thin volume, low power consumption, and being compatible with current semiconductor fabrication processes. Therefore, liquid crystal displays have gradually become the mainstream among various candidates of flat panel displays. In addition, because the driving integrated circuit (IC), used in the liquid crystal display, is one of the most important devices and is costly, how to assure that the driving IC is of good quality is a key to the quality of the liquid crystal display.

FIG. 1 shows an apparatus for burning a driving IC. The apparatus includes a circuit board 100 and a probe 102, in which the circuit board 100 has a testing point 104 thereon. The circuit board 100 transmits the desired programming data to a driving IC 106. The testing point 104, on the circuit board 100, is electrically connected to the driving IC 106 and electrically contacts with the probe 102, wherein the driving IC 106 is fabricated on a substrate 108. Further, a burning signal is input into the probe 102 and transmitted to the driving IC 106 through the testing point 104.

When the driving IC is burned, the burning signal is typically input into the probe 102, and then the desired programming data is transmitted from the circuit board 100 to the driving IC 106, to complete burning. However, one problem that the probe 102 does not electrically contact with the testing point 104 effectively usually happens, and the desired programming data cannot be burned into the driving IC 106 after complete the burning process. As a result, the yield rate of the products cannot be increased, and the production cost is also relatively increased.

For the foregoing reasons, there is a need to provide a testing apparatus or method, so as to make sure that the probe electrically contacts with the testing point before burning the driving IC, to avoid this type of error.

### SUMMARY

In accordance with one embodiment of the present invention, a testing apparatus is provided. The testing apparatus includes a circuit board and a first probe. The circuit board has a first testing point and a second testing point, in which the first testing point is electrically connected to an integrated circuit and the second testing point is electrically connected to the first testing point. The first probe is used for electrically contacting with the first testing point and transmits a signal to the integrated circuit through the first testing point. The second testing point is used for detecting if the first probe electrically contacts with the first testing point.

In accordance with another embodiment of the present invention, a testing method is provided for detecting if a first probe electrically contacts with a first testing point on a circuit board, in which the circuit board has a second testing point. This method is comprised of the following steps: connecting electrically the second testing point and the first testing point; providing a testing signal for the first probe; and detecting the second testing point to determine if the first probe electrically contacts with the first testing point.

For the foregoing embodiment of the present invention, the testing apparatus and method can be used, before burning the driving IC, to detect if the probe, for transmitting the burning signal, electrically contacts with the testing point on the circuit board indeed, so as to avoid a failed burning process and improve the burning process. Furthermore, the quality of the products can be relatively improved, and the production cost can be reduced as well.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the preferred embodiment, with reference made to the accompanying drawings as follows:

FIG. 1 shows an apparatus for burning a driving IC;

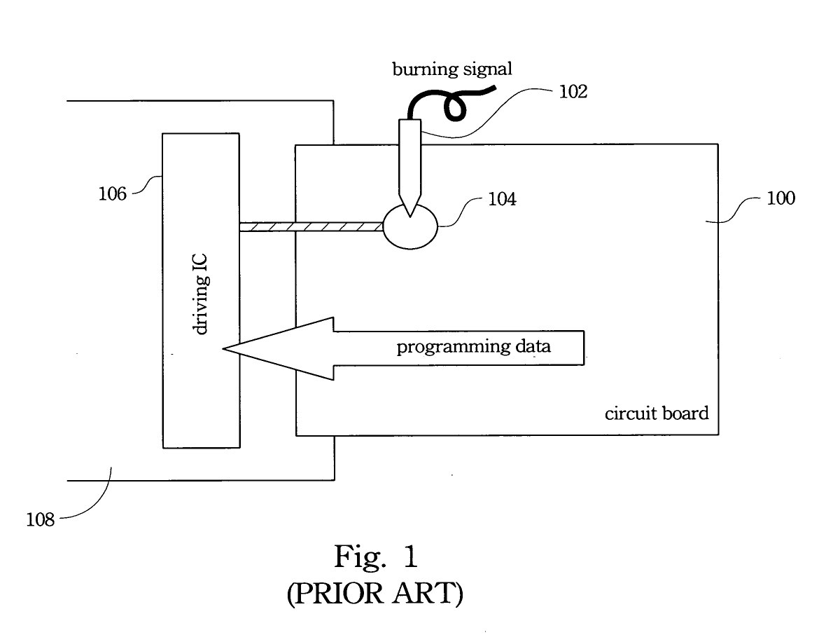

FIG. 2 shows the testing apparatus according to one embodiment of the present invention; and

FIG. 3 shows the testing method according to one embodiment of the present invention.

### DESCRIPTION OF THE PREFERRED EMBODIMENTS

Detailed illustrative embodiments of the present invention are disclosed herein. However, specific details disclosed herein are merely representative for purposes of describing exemplary embodiments of the present invention. This invention may, however, be embodied in many alternate forms and should not be construed as limited to the embodiments set forth herein.

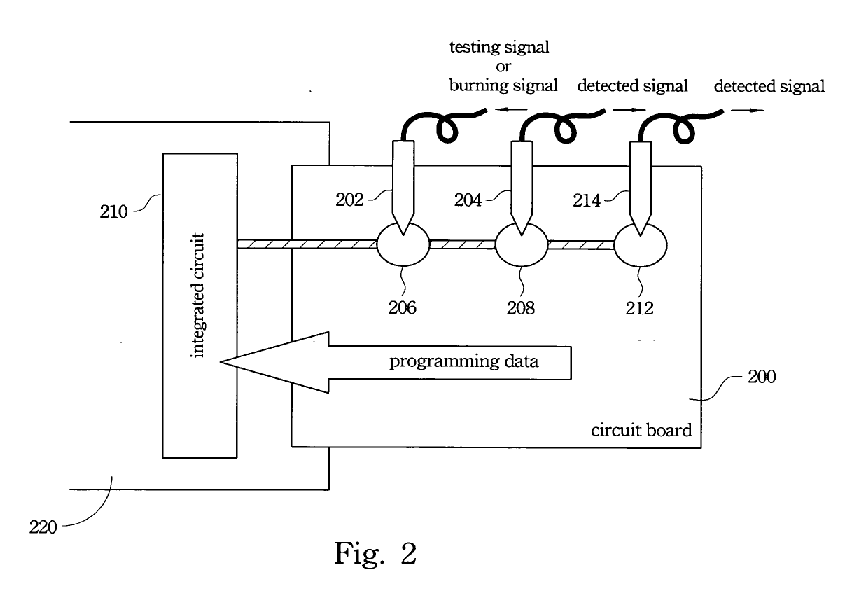

FIG. 2 shows the testing apparatus according to one embodiment of the present invention. The testing apparatus includes a circuit board 200, a first probe 202 and a second probe 204. The circuit board 200 transmits the desired programming data to an integrated circuit (IC) 210, and has a first testing point 206 and a second testing point 208 thereon, in which the first testing point 206 is electrically connected to the integrated circuit 210 and the second testing point 208 is electrically connected to the first testing point 206. Moreover, the foregoing integrated circuit 210 can be a driving device, such as driving IC, and fabricated on a substrate 220, and the substrate 220 can be a glass substrate or a film. Therefore, the integrated circuit 210 can be fabricated on a glass substrate by using a chip-on-glass (COG) process or fabricated on a film by using a chip-on-film (COF) process.

The first probe 202 is used for electrically contacting with the first testing point 206 and for transmitting a testing signal or a burning signal, used for a burning process, to the integrated circuit 210 through the first testing point 206. The second probe 204 electrically contacts with the second testing point 208, and is used for acquiring the signal from the second testing point 208 to determine if the first probe 202 electrically contacts with the first testing point 206 indeed.

The circuit board 200 can further include a third testing point 212 electrically connected to the second testing point 208, in accordance with a preferred embodiment of the present invention. Additionally, the foregoing testing apparatus can further include a third probe 214 electrically contacting with the third testing point 212. As a result, the signal from the third testing point 212 can be acquired by the third probe 214, and the third testing point 212 can also be used to detect if the first probe 202 electrically contacts with the first testing point 206 indeed, in case that the second probe 204 does not contact electrically with the second testing point 208 indeed. Moreover, the detecting manner can also be performed by detecting if the first probe 202 and the second probe 204 are conducted, or if the first probe 202 and the third probe 214 are conducted.

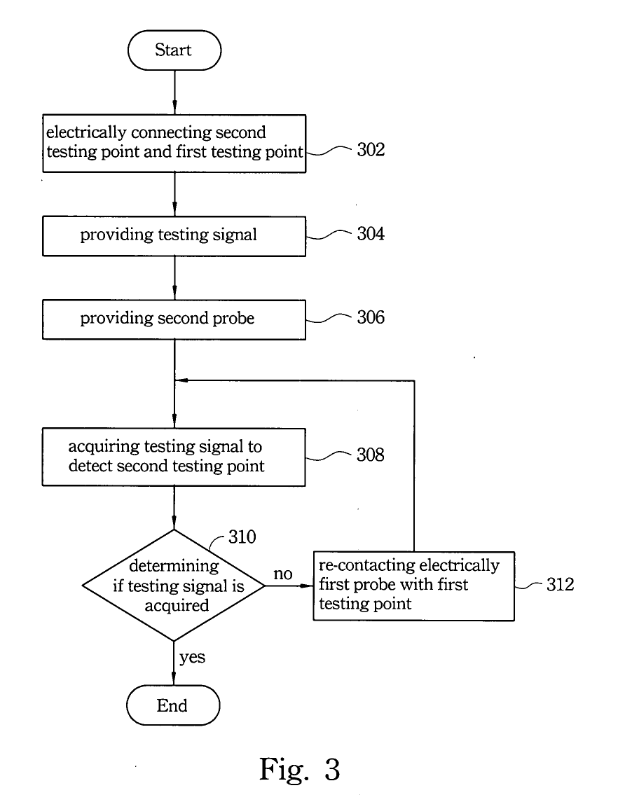

FIG. 3 shows the testing method according to one embodiment of the present invention. The testing method is used for detecting if the first probe electrically contacts with the first testing point on the circuit board, in which the circuit board has the second testing point. First, the second testing point and the first testing point are electrically connected (step 302), so that the signal, transmitted through the first testing point, can also be detected by the second testing point. Then, a testing signal, used for detection, is provided for the first probe (step 304).

Furthermore, a second probe can be further provided to electrically contact with the second testing point (step 306). After that, the testing signal, transmitted through the second testing point, is acquired by the second probe, so as to detect the second testing point (step 308) and to determine if the first probe electrically contacts with the first testing point indeed.

Then, if the first probe electrically contacts with the first testing point indeed is determined by if the testing signal is acquired by the second probe (step 310). If the second probe cannot acquire the testing signal, it is known that the first probe does not electrically contact with the first testing point indeed, and the first probe can be re-contacted electrically with the first testing point (step 312). After that, returning to the step 308, the testing signal, transmitted through the second testing point, is acquired by the second probe again, so as to detect the second testing point once more and to make sure that the first probe electrically contacts with the first testing point indeed, to complete the testing process.

After making sure that the first probe electrically contacts with the first testing point indeed, the burning signal can be input into the integrated circuit through the first probe, and the desired programming data can be provided for the integrated circuit through the circuit board, to complete the burning process.

For the foregoing embodiments of the present invention, the testing apparatus and method can be used, before burning the driving IC, to detect if the probe, for transmitting the burning signal, electrically contacts with the testing point on the circuit board indeed, so as to avoid the failure burning process and improve the burning process. Furthermore, the quality of the products can be relatively improved, and the production cost can be reduced as well.

As is understood by a person skilled in the art, the foregoing preferred embodiments of the present invention are illustrative of the present invention rather than limiting of the present invention. It is intended to cover various modifications and similar arrangements included within the spirit and scope of the appended claims, the scope of which should be accorded the broadest interpretation so as to encompass all such modifications and similar structures.

What is claimed is:

1. A testing apparatus, comprising:
a circuit board having a first testing point and a second testing point, wherein the first testing point is electrically connected to an integrated circuit and the second testing point is electrically connected to the first testing point; and
a first probe for electrically contacting with the first testing point and transmitting a signal to the integrated circuit through the first testing point;
wherein the second testing point is used for detecting if the first probe electrically contacts with the first testing point.

2. The testing apparatus as claimed in claim 1, further comprising:
a second probe electrically contacting with the second testing point.

3. The testing apparatus as claimed in claim 1, wherein the circuit board further comprising:
a third testing point electrically connected to the second testing point.

4. The testing apparatus as claimed in claim 3, further comprising:
a third probe electrically contacting with the third testing point.

5. The testing apparatus as claimed in claim 1, wherein the integrated circuit comprises a driving device.

6. The testing apparatus as claimed in claim 1, wherein the integrated circuit is fabricated on a glass substrate.

7. The testing apparatus as claimed in claim 1, wherein the integrated circuit is fabricated on a film by using a chip-on-film process.

8. A testing method for detecting if a first probe electrically contacts with a first testing point on a circuit board, the circuit board having a second testing point, the method comprising the steps of:
connecting electrically the second testing point and the first testing point;
providing a testing signal for the first probe; and
detecting the second testing point to determine if the first probe electrically contacts with the first testing point.

9. The method as claimed in claim 8, further comprising:
providing a second probe electrically contacting with the second testing point; and
acquiring the testing signal detected by the second probe through the second testing point to determine if the first probe electrically contacts with the first testing point.

10. The method as claimed in claim 8, further comprising:
re-contacting electrically the first probe with the first testing point when detecting the second testing point to be informed of the first probe not electrically contacting with the first testing point.
